(19) United States
(12) Patent Application Publication
(10) Pub. No.: US 2016/0315233 A1
(43) Pub. Date: Oct. 27, 2016

(54) SEMICONDUCTOR LIGHT-EMITTING DEVICE AND METHOD OF MAKING THE SAME

(71) Applicant: Aceplux Optotech Inc., Tainan City (TW)

(72) Inventor: Hsin-Ming LO, Pingtung County (TW)

(21) Appl. No.: 14/697,317

(22) Filed: Apr. 27, 2015

(51) Int. Cl. H01L 33/58; H01L 33/12; H01L 33/00; H01L 33/32

(52) U.S. Cl. CPC H01L 33/58; H01L 33/32; H01L 33/12; H01L 33/0075

(57) ABSTRACT

A semiconductor light-emitting device includes a base layer having a top surface, multiple light-transmissive members, a buffer layer, and a light-emitting epitaxial structure. The light-transmissive members are formed on the top surface of the base layer and spaced apart from one another. The buffer layer is made of a first group-III nitride material, and is formed to cover the light-transmissive members and the top surface of the base layer exposed from the light-transmissive members. The light-emitting epitaxial structure includes a first semiconductor layer formed on the buffer layer. The first semiconductor layer is made of a second group-III nitride material different from the first group-III nitride material.

### FIELD

The disclosure relates to a semiconductor light-emitting device, more particularly to a semiconductor light-emitting device including a plurality of light-transmissive members and a buffer layer, and a method of making the semiconductor light-emitting device.

### BACKGROUND

A high brightness light-emitting diode (HB-LED) made of a group-III nitride material emits light covering the visible light spectrum and is therefore widely used in various lighting applications, such as traffic lights and backlights for liquid crystal displays. Accordingly, the high brightness light emission diode has great developmental potential.

When an HB-LED is formed on a sapphire substrate, a dislocation density up to a range of 10⁸ to 10¹⁰/cm² may be formed due to large differences in lattice constant and thermal expansion coefficient between the group-III nitride material and the sapphire substrate. The dislocation may include misfit dislocation and thread dislocation. High dislocation density could result in deteriorated film quality, which leads to generation of heat and lowered internal quantum efficiency, which in turn leads to deterioration of overall brightness.

In addition, conventional metal organic chemical vapor deposition (MOCVD) and molecular beam epitaxy (MBE) techniques used for film deposition are time-consuming and results in higher overall manufacturing costs.

Furthermore, due to the high refractive index and low critical angle of group-III nitride materials, total internal reflection tends to occur so that light emitted by the LED cannot emit outward. In other words, light emitted by a light-emitting layer of the LED tends to be trapped inside the LED.

### SUMMARY

Therefore, an object of the disclosure is to provide a semiconductor light-emitting device that has reduced misfit dislocation and thread dislocation, improved epitaxial film quality, improved luminous efficiency, and reduced process time.

Another object of the disclosure is to provide a method of making the semiconductor light-emitting device.

According to one aspect of the present disclosure, a semiconductor light-emitting device includes a base layer having a top surface, a plurality of light-transmissive members, a buffer layer, and a light-emitting epitaxial structure.

The light-transmissive members are formed on the top surface of the base layer and are spaced apart from one another. The buffer layer is made of a first group-III nitride material and is formed to cover the light-transmissive members and the top surface of the base layer that are exposed from the light-transmissive members. The light-emitting epitaxial structure includes a first semiconductor layer that is formed on the buffer layer. The first semiconductor layer is made of a second group-III nitride material different from the first group-III nitride material.

According to another aspect of the present disclosure, a method of making the semiconductor light-emitting device includes:

providing a substrate;

forming a photoresist layer on the substrate and defining the photoresist layer into a mask;

dry-etching the substrate via the mask to form a patterned substrate that includes a plurality of spaced-apart light-transmissive members, followed by removing the mask from the patterned substrate;

depositing a buffer layer to cover the light-transmissive members and regions of the patterned substrate exposed from the light-transmissive members, the buffer layer being made of a first group-III nitride material; and

forming a light-emitting epitaxial structure onto the buffer layer, the light-emitting epitaxial structure having a first semiconductor layer that is formed on the buffer layer by hydride vapor phase epitaxy and that is made of a second group-III nitride material different from the first group-III nitride material.

### BRIEF DESCRIPTION OF THE DRAWINGS

Other features and advantages of the present disclosure will become apparent in the following detailed description of the embodiments with reference to the accompanying drawings, of which:

FIG. 1 is a schematic cross-sectional view of an exemplary embodiment of a semiconductor light-emitting device according to the present disclosure;

FIG. 2 is a fragmentary schematic view of the exemplary embodiment;

FIG. 3 is a scanning electron microscope (SEM) image showing a roughened interface formed between a first semiconductor layer and light-transmissive members in a semiconductor light-emitting device without a buffer layer;

FIG. 4 is an SEM image showing a uniform and smooth interface formed between a first semiconductor layer and a buffer layer in the exemplary embodiment of this disclosure;

FIG. 5 shows luminous efficiencies of the exemplary embodiment and a conventional semiconductor light-emitting device including a base layer that is roughened by etching;

FIG. 6 shows consecutive steps of a first method of making the exemplary embodiment; and

FIG. 7 shows consecutive steps of a second method of making the exemplary embodiment.

### DETAILED DESCRIPTION

Before the disclosure is described in greater detail with reference to the accompanying embodiments, it should be noted herein that like elements are denoted by the same reference numerals throughout the disclosure.

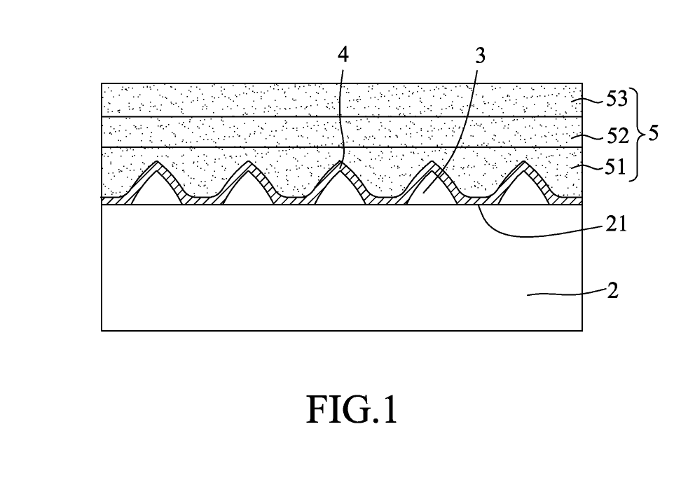

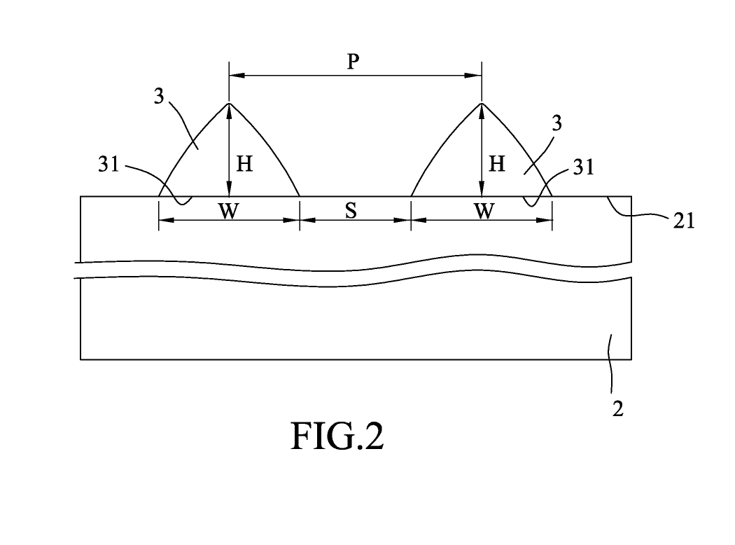

Referring to FIGS. 1 and 2, an exemplary embodiment of a semiconductor light-emitting device according to the present disclosure includes a base layer 2 having a top surface 21, a plurality of light-transmissive members 3, a buffer layer 4 and a light-emitting epitaxial structure 5.

The light-transmissive members 3 are formed on the top surface 21 of the base layer 2, spaced apart from one another, and have a refractive index not greater than that of the base layer 2.

In certain examples, the base layer 2 is made of a material including, e.g., sapphire (Al₂O₃), silicon carbide (SiC), silicon (Si), gallium arsenide (GaAs), zinc oxide (ZnO), and a hexagonal-crystal-based material. The light-transmissive members 3 are made of a material that has a transmittance and refractive index both smaller than those of the base layer 2 and a melting point not smaller than 1000° C., and that includes, e.g., silicon oxide (SiOₓ), silicon oxynitride (SiOₓN_{y}), and magnesium fluoride (MgF₂). In other examples, the light-transmissive members 3 and the base layer 2 may be made from the same material.

Specifically, in FIG. 2, each of the light-transmissive members 3 is configured into a substantial cone shape and has a bottom surface 31 connected to the top surface 21 of the base layer 2. The bottom surface 31 has a maximum width (W). Each of the light-transmissive members 3 has a height (H) from the bottom surface 31 to a vertex thereof. By controlling the height (H) and the maximum width (W) of each of the light-transmissive members 3, the travelling path of the light that passes through the light-transmissive members 3 can be easily diverted. In other words, when light emitted by the semiconductor light-emitting device is trapped owing to total internal reflection, the light will be reflected to the light-transmissive members 3 and then again reflected or refracted by the light-transmissive members 3 to change the light emitting angle thereof. Therefore, the light may be capable of exiting the semiconductor light-emitting device so as to improve the luminous efficiency of the semiconductor light-emitting device.

The buffer layer 4 is made of a first group-III nitride material and is formed to cover the light-transmissive members and the top surface 21 of the base layer 2 exposed from the light-transmissive members 3. The light-emitting epitaxial structure 5 includes a first semiconductor layer 51 that is formed on the buffer layer 4 and that is made of a second group-III nitride material different from the first group-III nitride material. The light-emitting epitaxial structure 5 further includes a light-emitting layer 52 formed on the first semiconductor layer 51, and a second semiconductor layer 53 formed on the light-emitting layer 52 oppositely of the first semiconductor layer 51. In certain examples of this disclosure, the first semiconductor layer 51, the light-emitting layer 52 and the second semiconductor layer 53 respectively correspond to an N-type semiconductor layer, an active layer and a P-type semiconductor layer, and the buffer layer 4 and the first semiconductor layer 51 are respectively made from aluminum nitride (AlN) and gallium nitride (GaN). However, the materials of the buffer layer 4 and the first semiconductor layer 51 are not limited to those in the examples as long as the materials of the buffer layer 4 and the first semiconductor layer 51 are different but have similar lattice constants. Since the viable structures and materials of the light-emitting layer 52 and the second semiconductor layer 53 are well known in the art and are not the essence of the present disclosure, detailed descriptions thereof will not be provided hereinafter.

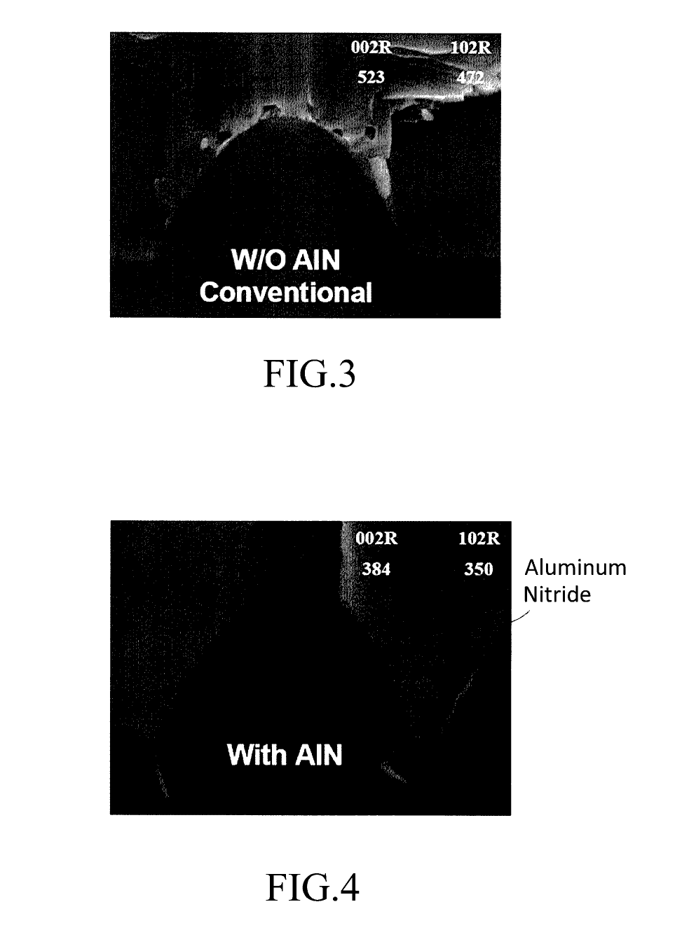

The effect of the buffer layer 4 is shown in FIGS. 3 and 4. In FIG. 3, the first semiconductor layer 51 is directly formed on the light-transmissive members 3, and a roughened interface is formed between the first semiconductor layer 51 and the light-transmissive members 3. In contrast, the semiconductor light-emitting device in FIG. 4 is formed with the buffer layer 4 between the light-transmissive members 3 and the first semiconductor layer 51, and a uniform and smooth interface is formed between the first semiconductor layer 51 and the buffer layer 4. Therefore, with the buffer layer 4, the density of misfit dislocation may be reduced in the subsequent epitaxial process. The luminous efficiency of the semiconductor light-emitting device is thus improved.

In order to form a continuous buffer layer 4, the aluminum nitride preferably has a thickness greater than 100 Å. However, due to the stress difference between the base layer 2 and the buffer layer 4, film cracking may occur during the subsequent film-forming process when the thickness of the buffer layer 4 is greater than 1000 Å. Therefore, the thickness of the buffer layer 4 preferably ranges from 100 Å to 1000 Å. When the first semiconductor layer 51 has a thickness smaller than 5 μm, misfit dislocation in the subsequent epitaxial process cannot be effectively prevented. Moreover, the luminous efficiency of the semiconductor light-emitting device that includes the first semiconductor layer 51 having a thickness greater than 10 μm is equivalent to the luminous efficiency of the semiconductor light-emitting device that includes the first semiconductor layer 51 having a thickness ranging from 5 μm to 10 μm. Therefore, the thickness of the first semiconductor layer 51 is preferably controlled to range from 5 μm to 10 μm for cost considerations. In this embodiment, by virtue of the formation of the aluminum nitride buffer layer 4 having the smaller thickness between the base layer 2 and the first semiconductor layer 51 the larger thickness, misfit dislocation can be alleviated and film cracking caused by large stress difference between the first semiconductor layer 51 and the base layer 2 can be prevented.

It is worth mentioning that the luminous efficiency of the semiconductor light-emitting device can be improved by adjusting the maximum width (W) of the bottom surface 31 and the height (H) of each of the light-transmissive members 3. When the ratio of the height (H) to the maximum width (W) is too small, the probability of light exiting the semiconductor light-emitting device by refraction or reflection would be lowered due to excessive incident angle of light entering each of the light-transmissive members 3, which is caused by insufficient height (H) of each of the light-transmissive members 3. When the ratio of the height (H) to the maximum width (W) is too large, it would be difficult to form a uniform film of the first semiconductor layer 51 due to excessive height (H) of each of the light-transmissive members 3. In the exemplary embodiment, the ratio of the height (H) to the maximum width (W), i.e., the height-to-width ratio, is not smaller than 0.6, preferably ranging from 0.60 to 0.65. Relations between luminous efficiency and the height-to-width ratio (H/W ratio) are shown in Table 1.

TABLE 1

| H/W Ratio | 0.59 | 0.60 | 0.63 | 0.65 |
|---|---|---|---|---|
| Luminous Efficiency | 255 mW | 260 mW | 265 mW | 268 mW |

According to Table 1, when the H/W ratio is smaller than 0.60, the luminous efficiency of the semiconductor light-emitting device is insufficient and may not meet industrial requirements. When the H/W ratio is larger than 0.65, it would be difficult to form a uniform film of the first semiconductor layer 51 due to excessive height (H). Therefore, the H/W ratio is controlled to range from 0.60 to 0.65.

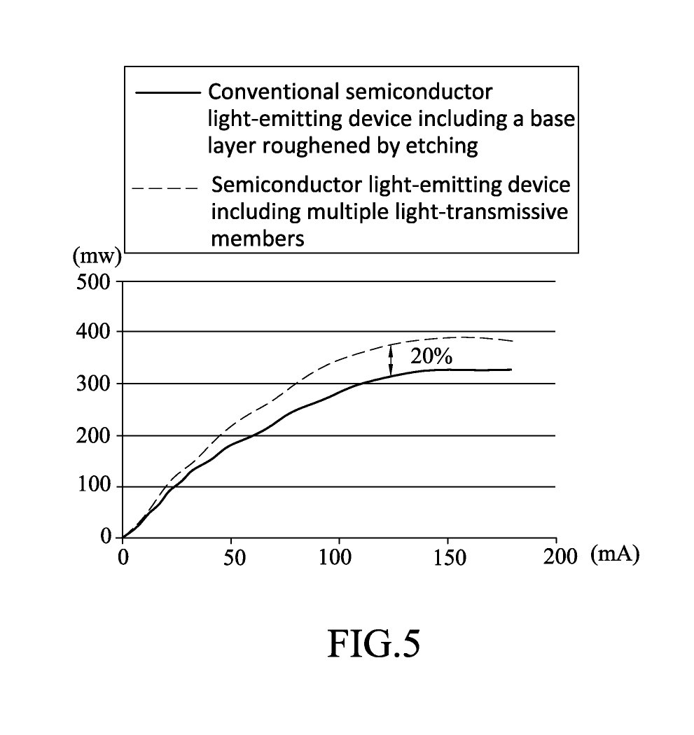

FIG. 5 shows a 20% increase in the luminous efficiency of the semiconductor light-emitting device including the light-transmissive members 3 compared to a conventional semiconductor light-emitting device including a base layer that is roughened by etching. The light-transmissive members 3 are periodically arranged. Two adjacent ones of the light-transmissive members 3 are spaced apart from each other by a distance (S) not greater than 1 μm, and vertices of two adjacent ones of the light-transmissive members 3 are spaced apart from each other by a distance (P) of 3 μm (see FIG. 2). Besides adjusting the H/W ratio, the distances (S) and (P) can also be adjusted to increase the density of the light-transmissive members 3 and achieve better reflection and refraction. Therefore, light emitted by the semiconductor light-emitting device can exit outward more effectively. It is worth mentioning that defective light-transmissive members 3 may result if the light-transmissive members 3 are connected to one another. Therefore, the light-transmissive members 3 in the present disclosure are spaced apart from one another.

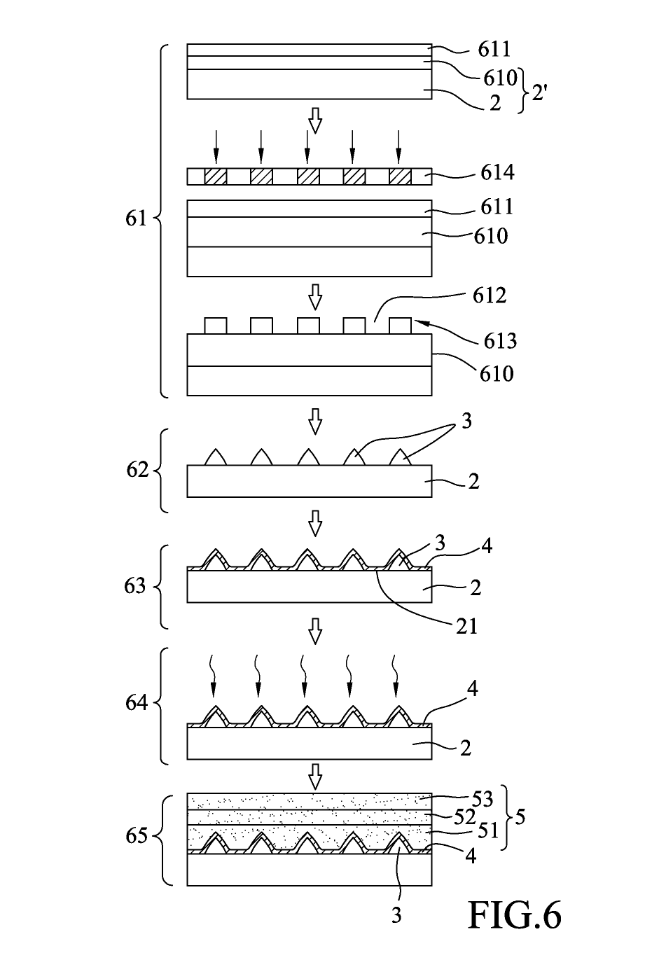

FIG. 6 shows consecutive steps of a first method of making the semiconductor light-emitting device of the exemplary embodiment of the present disclosure. The method includes a mask defining step 61, a light-transmissive member forming step 62, a buffer layer depositing step 63, an annealing step 64 and an epitaxy step 65.

In the mask defining step 61, the base layer 2 is first provided, and a light transmissive layer 610 is formed on the base layer 2 so as to provide a substrate 2′ with a two-layer structure. The light transmissive layer 610 is made from a light transmissive material. Then, a photoresist layer 611 is formed on the light transmissive layer 610 of the substrate 2′ and is defined into a mask 613 having a plurality of spaced apart openings 612. Parts of the light transmissive layer 610 are exposed from the openings 612 of the mask 613.

To be more specific, depending on practical requirements, the photoresist layer 611 may be a positive photoresist or a negative photoresist. The photoresist layer 611 is defined into the mask 613 through a photolithographic technique using a pre-determined photomask 614. That is, in the case of a positive photoresist, parts of the photoresist layer 611 not shaded by the photomask 614 will be removed in subsequent photolithographic process to form the mask 613 with the spaced-apart openings 612 that exposes the part of the light transmissive layer 610.

In the light-transmissive member forming step 62, the light transmissive layer 610 is dry-etched via the mask 613 until the top surface 21 of the base layer 2 is exposed so as to form the light transmissive layer 610 into a plurality of the light-transmissive members 3 that are spaced apart from one another. A patterned substrate that includes the base layer 2 and the light-transmissive members 3 is thus formed. The mask 613 is then removed from the patterned substrate using a resist removal process.

To be more specific, the light transmissive layer 610 is anisotropically dry-etched via the mask 613 to form the spaced-apart and substantially cone-shaped light-transmissive members 3. The anisotropic dry-etching is conducted under a radio frequency power ranging from 200 watts to 400 watts, and with a fluorine-containing etching gas, such as tetrafluoromethane (CF₄), sulfur hexafluoride (SF₆), fluoroform (CHF₃), etc.

In the buffer layer depositing step 63, the buffer layer 4 is formed to cover the light-transmissive members 3 and top surface 21 of the base layer 2 exposed from the light-transmissive members 3 by depositing the first group-III nitride material through the physical vapor deposition (PVD) technique.

To be more specific, in the buffer layer depositing step 63, the first group-III nitride material is formed onto the light-transmissive members 3 and the exposed top surface 21 of the base layer 2 by electron beam gun evaporation or sputtering techniques. In this embodiment, electron beam gun evaporation technique is used. A nitrogen plasma is generated and bombards a target of the first group-III nitride material to deposit a layer of the first group-III nitride material onto the light-transmissive members 3 and the exposed top surface 21 so as to form the buffer layer 4. In an example of this disclosure, the temperature used in the electron beam gun evaporation technique is not lower than 600° C. and the buffer layer 4 is an aluminum nitride film with a thickness ranging from 100 Å to 1000 Å. With the use of the electron beam gun evaporation technique, the buffer layer 4 may be uniformly formed on and completely cover the light-transmissive members 3 and the exposed top surface 21 and may effectively alleviate accumulated stress and dislocation density caused by the lattice difference between the light-transmissive members 3 and the subsequently deposited N-type first semiconductor layer 51.

After the buffer layer depositing step 63, the annealing step 64 is conducted in a high temperature furnace at a temperature not lower than 1000° C. for modifying the film properties of the buffer layer 4 and enhancing the bonding strength between the buffer layer 4 and the patterned substrate.

After the annealing step 64, the epitaxy step 65 is conducted to form the light-emitting epitaxial structure 5 on the buffer layer 4. The first semiconductor layer 51 of the light-emitting epitaxial structure 5 is formed by depositing the second group-III nitride material onto the buffer layer 4 using the hydride vapor phase epitaxy (HVPE) technique.

As mentioned above, the buffer layer 4 and the first semiconductor layer 51 may be made of other group-III nitride materials according to practical requirements, as long as the materials of the buffer layer 4 and the first semiconductor layer 51 are different but have similar lattice constants. Compared with the metal organic chemical vapor deposition (MOCVD) and the molecular beam epitaxy (MBE) techniques, the hydride vapor phase epitaxy (HVPE) technique has superior film growth rate (about 4 times faster) and lower equipment and processing costs, and is therefore more cost-effective.

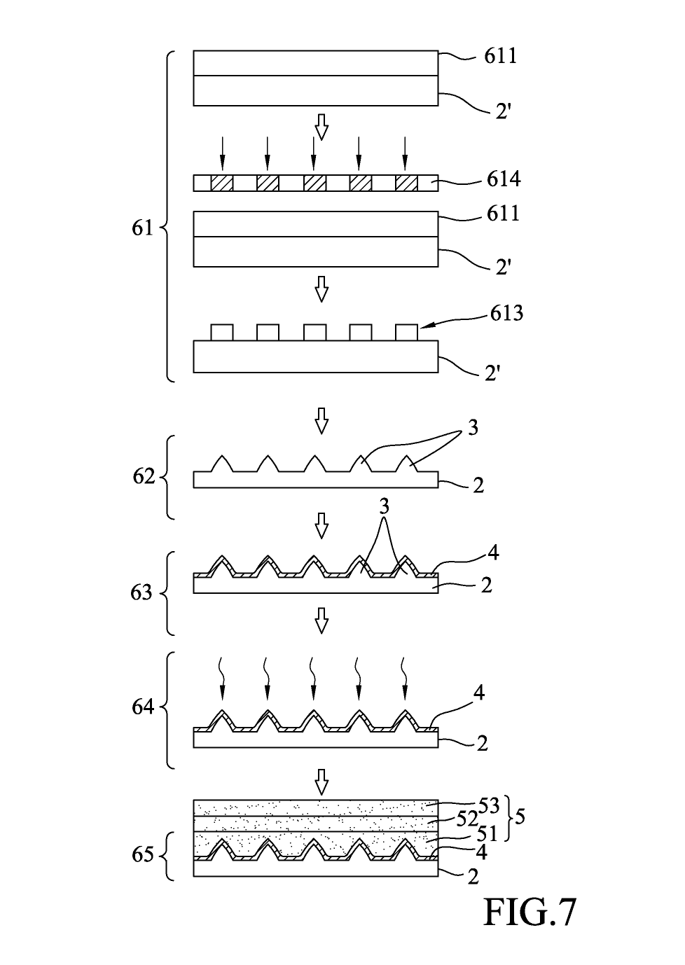

FIG. 7 shows consecutive steps of a second method of making the semiconductor light-emitting device of the exemplary embodiment of the present disclosure. The second method is similar to the first method except that, in the mask defining step 61 of the second method, the light transmissive layer 610 is omitted and the photoresist layer 611 is directly formed on the substrate 2′. That is, in the second method, the substrates 2′ has a single-layer structure and is composed of a light-transmissive material. The photoresist layer 611 is defined into the mask 613 by the photolithographic technique with the photomask 614. In the light-transmissive member forming step 62 of the second method, the substrate 2′ is anisotropically dry-etched via the mask 613 to form the base layer 2 and the light-transmissive members 3 that are spaced apart from one another. Each of the light-transmissive members 3 has a substantial cone shape. In the second method, the light-transmissive members 3 and the base layer 2 are made from the same material.

To sum up, by depositing the buffer layer 4 on the light-transmissive members 3, the interface between the buffer layer 4 and the first semiconductor layer 51 is more uniform and smooth with less thread dislocation. The luminous efficiency of the semiconductor light-emitting device is therefore improved. Moreover, the hydride vapor phase epitaxy technique used to grow the first semiconductor layer 51 can shorten process time and lower process costs. Moreover, the luminous efficiency of the semiconductor light-emitting device may be improved by adjusting the maximum width (W) of the bottom surface 31, the height (H) of each of the light-transmissive members 3, the distance (S) of two adjacent ones of the light-transmissive members 3 and the distance (P) of vertices of two adjacent ones of the light-transmissive members 3 to increase the density of the light-transmissive members 3 and thereby achieving better reflection and refraction.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A semiconductor light-emitting device, comprising:
a base layer having a top surface;
a plurality of light-transmissive members formed on said top surface of said base layer and spaced apart from one another;
a buffer layer made of a first group-III nitride material and formed to cover said light-transmissive members and said top surface of said base layer exposed from said light-transmissive members; and
a light-emitting epitaxial structure including a first semiconductor layer formed on said buffer layer,
wherein said first semiconductor layer is made of a second group-III nitride material different from said first group-III nitride material.

2. The semiconductor light-emitting device according to claim 1, wherein said light-transmissive members have a refractive index not greater than that of said base layer.

3. The semiconductor light-emitting device according to claim 2, wherein said light-transmissive members have a melting point not smaller than 1000° C.

4. The semiconductor light-emitting device according to claim 3, wherein said light-transmissive members are made of a material selected from the group consisting of silicon oxide, silicon oxynitride, and magnesium fluoride.

5. The semiconductor light-emitting device according to claim 4, wherein said base layer is made from a material selected from the group consisting of sapphire, silicon carbide, silicon, gallium arsenide, zinc oxide, and a hexagonal-crystal-based material.

6. The semiconductor light-emitting device according to claim 1, wherein said base layer and said light-transmissive members are made from the same material, which is selected from the group consisting of sapphire, silicon carbide, silicon, gallium arsenide, zinc oxide, and a hexagonal-crystal-based material.

7. The semiconductor light-emitting device according to claim 1, wherein each of said light-transmissive members is configured into a substantial cone shape and has a height-to-width ratio that is not smaller than 0.6.

8. The semiconductor light-emitting device according to claim 1, wherein two adjacent ones of said light-transmissive members are spaced apart from each other by a distance not greater than 1 μm.

9. The semiconductor light-emitting device according to claim 1, wherein said first group-III nitride material is aluminum nitride.

10. The semiconductor light-emitting device according to claim 1, wherein said second group-III nitride material is gallium nitride.

11. The semiconductor light-emitting device according to claim 1, wherein said buffer layer has a thickness ranging from 100 Å to 1000 Å.

12. The semiconductor light-emitting device according to claim 1, wherein said first semiconductor layer of said light-emitting epitaxial structure has a thickness ranging from 5 μm to 10 μm.

13. The semiconductor light-emitting device according to claim 1, wherein said light-emitting epitaxial structure further includes a light-emitting layer formed on said first semiconductor layer, and a second semiconductor layer formed on said light-emitting layer oppositely of said first semiconductor layer.

14. A method of making a semiconductor light-emitting device, comprising:
providing a substrate;
forming a photoresist layer on the substrate and defining the photoresist layer into a mask;
dry-etching the substrate via the mask to form a patterned substrate that includes a plurality of spaced-apart light-transmissive members, followed by removing the mask from the patterned substrate;
depositing a buffer layer to cover the light-transmissive members and regions of the patterned substrate exposed from the light-transmissive members, the buffer layer being made of a first group-III nitride material; and
forming a light-emitting epitaxial structure onto the buffer layer, the light-emitting epitaxial structure having a first semiconductor layer that is formed on the buffer layer by hydride vapor phase epitaxy and that is made of a second group-III nitride material different from the first group-III nitride material.

15. The method of claim 14, wherein the provided substrate includes a light-transmissive layer, the photoresist layer is formed on the light-transmissive layer, and the forming of the light-transmissive members is conducted by dry-etching the light-transmissive layer of the substrate.

16. The method of claim 14, further comprising, after the depositing step, annealing the buffer layer.

17. The method of claim 14, wherein the depositing step is conducted by electron beam gun evaporation or sputtering.

18. The method of claim 14, wherein the buffer layer is formed to have a thickness ranging from 100 Å to 1000 Å.

19. The method of claim 14, wherein the first semiconductor layer of the light-emitting epitaxial structure is formed to have a thickness ranging from 5 μm to 10 μm.
